(19) United States
(12) Patent Application Publication
(10) Pub. No.: US 2025/0296470 A1
(43) Pub. Date: Sep. 25, 2025

(54) SYSTEM AND METHOD FOR CONTROLLING A VEHICLE BATTERY PACK BASED ON ESTIMATED & VERIFIED OPEN CIRCUIT VOLTAGE

(71) Applicant: Ford Global Technologies, LLC, Dearborn, MI (US)

(72) Inventors: Donnell Matthew Washington, Northville, MI (US); Yonghua Li, Ann Arbor, MI (US); Michael David Beeney, Canton, MI (US); Gabrielle Vuylsteke, Ferndale, MI (US); Jennifer Miller, Royal Oak, MI (US); Andrea Cordoba Arenas, Ann Arbor, MI (US); Bowen Zhang, Farmington Hills, MI (US); Matthew Allen Tomai, Troy, MI (US); Laurie Ann Ramroth, Plymouth, MI (US)

(21) Appl. No.: 18/613,450

(22) Filed: Mar. 22, 2024

(51) Int. Cl. B60L 58/12; B60L 53/63; B60L 58/18; G01R 31/388

(52) U.S. Cl. CPC B60L 58/12; B60L 53/63; B60L 58/18; G01R 31/388; B60L 2240/547; B60L 2260/44

(57) ABSTRACT

A system for an electrified vehicle (EV) having a battery pack includes a vehicle controller configured to charge and discharge the battery pack according to power limits defined at activation of the EV by a first open circuit voltage (OCV) estimated after a last deactivation of the EV based on voltages measured for a first duration after the last deactivation in response to the first OCV being within an OCV estimation threshold of a second OCV estimated after activation of the EV based on at least a portion of the voltage measured for the first duration and voltages measured prior to a contactor closing to activate the EV.

### TECHNICAL FIELD

The present disclosure generally relates to managing and/or controlling a battery pack for an electrified vehicle based, at least, on an open circuit voltage.

### BACKGROUND

An electrified vehicle (EV) includes a battery pack, sometimes referred to as a traction battery, for providing power to electric motors to propel the EV. One or more operational characteristics of the battery pack, such as power limits and state of charge (SOC), may be estimated to control the charge and discharge operation of the battery pack.

In a non-limiting example, the EV includes a battery management module (BMM) and a control system. Generally, during a discharge operation (e.g., driving of the EV), the BMM is configured to estimate SOC of the battery pack, and the control system is configured to control various devices/subsystems within the EV by, for example, determining how much power can be drawn from the battery pack using the operational characteristics, inputs from a user, power demand of devices (e.g., motors, air condition system, etc.), and/or among other information. For a charge operation, the BMM is configured to provide a charge current/voltage request to the control system, which in return controls the EV to begin charging the battery pack (e.g., control an electric vehicle supply equipment (EVSE)).

### SUMMARY

In one form, the present disclosure is directed to a system for an electrified vehicle (EV) having a battery pack. The system includes a vehicle controller configured to charge and discharge the battery pack according to power limits defined at activation of the EV by a first open circuit voltage (OCV) estimated after a last deactivation based on voltages measured for a first duration after the last deactivation in response to the first OCV being within an OCV estimation threshold of a second OCV estimated after activation of the EV based on at least a portion of the voltage measured for the first duration and voltages measured prior to a contactor closing to activate the EV.

In one form, the present disclosure is directed to a system for an electrified vehicle (EV) having a battery pack. The system includes a vehicle controller configured to charge and discharge the battery pack, having a plurality of battery cells, according to power limits defined at activation of the EV by an estimated open circuit voltage (OCV) based on a cell OCV for each of the battery cells that is estimated using a group OCV associated with each of the battery cells assigned to a cell group.

In one form, the present disclosure is directed to a method of controlling an electrified vehicle (EV) having a battery pack including a plurality of battery cells. The method includes, responsive to a deactivation request, opening one or more contactors to electrically decouple the battery pack from a charge-discharge system of the EV. The method further includes, responsive to an activation, closing the one or more contactors to electrically couple the battery pack to the charge-discharge system, and charging and discharging the battery pack according to power limits defined at activation of the EV by a first open circuit voltage (OCV) estimated after a last deactivation of the EV based on voltages measured for a first duration after the last deactivation in response to the first OCV being within an OCV estimation threshold of a second OCV estimated after activation of the EV based on at least a portion of the voltage measured for the first duration and voltages measured prior to a contactor closing to activate the EV.

### BRIEF DESCRIPTION OF THE DRAWINGS

FIG. 1 is an example block diagram of an electrified vehicle (EV) in accordance with the present disclosure;

FIG. 2 is a block diagram of a battery pack of the EV in accordance with the present disclosure;

FIG. 3 is a block diagram of a battery management module of the EV in accordance with the present disclosure;

FIG. 4 is a flowchart of an example battery cell group classifier routine in accordance with the present disclosure;

FIG. 5 is a flowchart of an example group OCV estimation routine in accordance with the present disclosure;

FIGS. 6A and 6B are flowcharts of an example open circuit voltage estimation routine in accordance with the present disclosure; and

FIG. 7 is a flowchart of an example verification routine in accordance with the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Generally, to manage a battery pack in an electrified vehicle (EV), a vehicle system of the EV needs to know a state of charge (SOC) of the battery pack to estimate the power capability/power limit of the battery pack. For most battery chemistries, the SOC is estimated based on an open circuit voltage (OCV) of the battery pack, which is the voltage of the battery pack at rest. In a non-limiting example, for hybrid electric vehicles (HEV), with the sizes of the battery cells typically on the order of five (5) ampere-hours, the OCV may stabilize within 30 minutes, but may take longer at colder temperatures. Specifically, stabilization is when the active material equally distributes (through diffusion) across the thickness of an electrode, and the time it takes to reach stabilization may be referred to as equilibrium time or stabilization time for the battery cell. Battery charge and discharge reactions occur at the electrode surface. As battery cells get bigger (e.g., increase in size), the electrodes tend to get thicker and thus, the equilibrium time may increase under the same temperature and state of charge (SOC). Some battery cells for EVs may require a few hours (e.g., over 3 hours) for the OCV to stabilize, which is longer at colder temperatures.

In various situations, it may be difficult for the EV to rest (i.e., no charging or discharging) for such long equilibrium times. For example, in one situation, a user of the EV may stop at a restaurant for a meal, which may only take one to two hours. In another example, the user may stop at a charging station, and the amount of time it takes between turning the EV off to charging the battery pack may be mere minutes.

Furthermore, the number of battery cells employed in the battery pack of the EV may also influence the detection of the OCV, which may be measured for each battery cell. Specifically, some EVs have about 100 cells in series, and with the EV moving towards higher electric power systems (e.g., 800V to 1200V), the number of battery cells may double or even triple, thereby increasing computational requirements of the vehicle system.

New EV battery warranty protocols may also require the EV to detect a state of certified energy” (SOCE) or state of health (SOH), which is the amount of energy a battery pack can deliver for standard drive cycles relative to that when the battery pack was new. Accordingly, the SOC at rest derived from the OCV should be accurate to improve accuracy of capacity, where in terms of capacity estimates, 2% SOC error is relative to the SOC window the customer is operating in.

The present disclosure is generally directed to a vehicle system configured to charge/discharge a battery pack in accordance with a power limit that is defined by an estimated OCV. In one form, to reduce computational demand of the vehicle system, the OCV is estimated by grouping battery cells having similar voltage measurements and estimating a group OCV for each group of battery cells. The OCV for the battery pack is estimated based on a cell OCV for each battery cell that is estimated using the group OCV associated with each battery cell.

In one form, prior to using the estimated OCV, the vehicle system may also confirm whether the estimated OCV is within an OCV estimation threshold. Specifically, a first OCV is estimated for the battery pack based on voltages measured for a first duration after the last deactivation of the EV and a second OCV estimated after the EV is activated based on at least some of the voltages measured after the last deactivation and at least one voltage measured after activation. In a non-limiting example, the second OCV is estimated using voltages measured at time=0 and 60 seconds after the last deactivation, and a voltage measured at activation (i.e., V(t_{Key-On})). The first OCV is employed to define the power limits in response to the first OCV being within the OCV estimation threshold of the second OCV. If the first OCV is not within the OCV estimation threshold, then the vehicle system does not use the first OCV to define the power limits. This allows the vehicle system to employ various OCV estimation techniques while verifying the accuracy of the estimation.

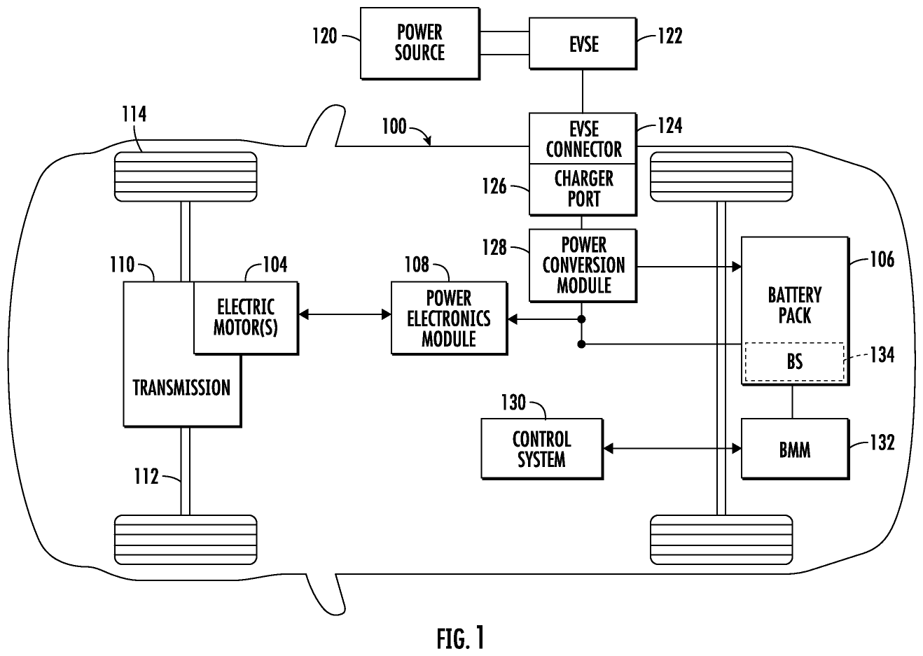

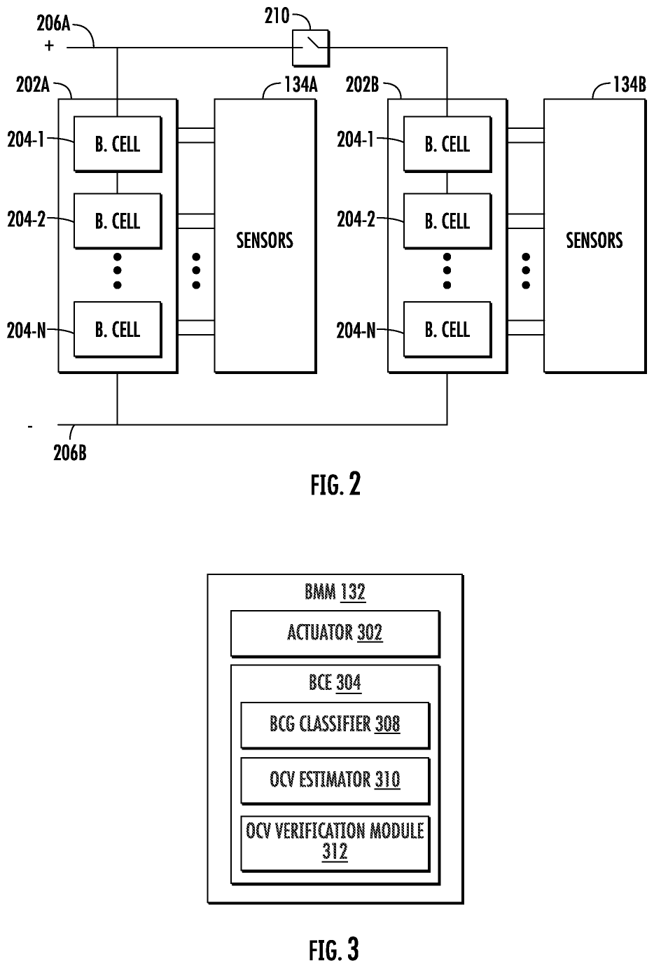

Referring to FIGS. 1 and 2, in one form, an EV 100 is provided as a full battery electric vehicle (BEV) powered by electric motors. In a non-limiting example, the EV 100 includes a powertrain system having one or more electric motors 104 (i.e., electric machines), a battery pack 106 (i.e., a traction battery), and a power electronics module 108. The EV 100 of the present disclosure does not include an engine, and thus, the battery pack 106 provides all of the propulsion power. In other variations, the present disclosure may be applied to other types of EVs such as a hybrid electric vehicle (plug-in or non-plug-in) having an engine, fuel cell electric vehicles (FCEV), and therefore, is not limited to pure battery powered EVs. In addition, the EV is not limited to four-wheel automobiles and may apply to scooters, three-wheel vehicles, aerial vehicles, and/or among other vehicles.

The electric motor 104 provides power movement of the EV 100, and in a non-limiting example, is mechanically connected to a transmission 110 that is mechanically connected to a drive shaft 112, which is mechanically connected to wheels 114 of the EV 100. In addition to providing propulsion power, the electric motor 104 may be configured to operate as a generator to recover energy that may normally be lost as heat in a friction braking system of EV 100.

The battery pack 106 provides a high-voltage (HV) direct current (DC) output that is employed to power the electric motor 104 via the power electronics module 108, and while one battery pack 106 is shown, the EV 100 may include multiple battery packs. In one form, the power electronics module 108, which includes an inverter, provides a bidirectional transfer energy between the battery pack 106 and the electric motor 104. Specifically, as known, the power electronics module 108 converts the DC voltage to a three-phase AC current to operate the electric motor 104, and in a regenerative mode, the power electronics module 108 converts three-phase AC current from the electric motor 104, which is acting as a generator, to DC voltage compatible with the battery pack 106.

The battery pack 106 may be rechargeable by an external power source 120 (e.g., the power grid/network), which is electrically connected to an electric vehicle supply equipment (EVSE) 122. The EVSE 122 provides circuitry and controls to manage the transfer of electrical energy between the external power source 120 and the EV 100. The external power source 120 may provide DC or AC electric power to the EVSE 122. The EVSE 122 may have a charge connector 124 for plugging into a charge port 126 of the EV 100.

The EV 100 may further include a power conversion module 128 that is an on-board charger having a DC/DC converter to condition power supplied from the EVSE 122 and provide the proper voltage and current levels to the battery pack 106. The power conversion module 128 may interface with the EVSE 122 to coordinate the delivery of power to the battery pack 106.

In one form, the EV 100 includes a control system 130 to coordinate the operation of the various components. The control system 130 includes electronics, software, or both, to perform the necessary control functions for operating the EV 100. The control system 130 may be a combination vehicle control system and powertrain control module (VSC/PCM). Although the control system 130 is shown as a single device, the control system 130 may include multiple controllers in the form of multiple hardware devices, or multiple software controllers with one or more hardware devices. In this regard, a reference to a “controller” herein may refer to one or more controllers.

In one form, the EV 100 includes a battery management module (BMM) 132 configured to estimate one or more operating characteristics of the battery pack 106 and provide one or more of the operating characteristics to the control system 130, which controls operation of the battery pack 106 (e.g., control charging/discharging of the battery pack 106). In a non-limiting example, during drive operation, the BMM 132 provides operational characteristics such as, but not limited to, power limit and/or SOC, to the control system 130, which determines how much power to draw from the battery pack 106. During a charge operation, the BMM 132 notifies the control system 130 of how much power is needed to charge the battery pack 106. The BMM 132 forms part of the vehicle control system with the control system 130, and while illustrated separate from the control system 130, may be integrated with the control system 130. In one form, the BMM 132 and the control system 130 may be referred to as a vehicle controller.

In one form, the BMM 132 is in communication with one or more sensors (also referred to as a battery sensor (BS)) 134 provided with the battery pack 106 to estimate characteristics of the battery pack 106, such as but not limited to, electric current, voltage, and/or temperature.

Among other components, the battery pack 106 includes multiple battery arrays 202A and 202B (collectively “arrays 202”), where each array 202 includes a plurality of battery cells 204-1 to 204-N (collectively “cells 204”) connected in series (FIG. 2). The arrays 202 are connected to a positive power bus 206A and a negative power bus 206B (collectively “power buses 206”). While two arrays 202 are provided, the battery pack 106 may include one or more arrays 202, and should not be limited to the example provided herein. In addition, the arrays 202 and/or cells 204 of the battery pack 106 may be configured in various suitable ways. In a non-limiting example, the battery pack 106 may be configured to have the arrays 202 in series, and for each array 202, the cells 204 are provided in parallel.

The sensors 134 includes one or more sensors 134A and 134B for the arrays 202. In one form, the sensors 134 include voltage sensors and current sensors for measuring voltage and/or electric current of the array 202 and in some variations, of each battery cell 204. It should be readily understood that the sensors 134 may include other sensors, such as but not limited to, temperature sensors for measuring a temperature of the array 202 and/or the battery pack 106.

In one form, one or more contactors 210 are provided to inhibit or permit electric current from traveling through the power buses 206 to/from the battery pack 106. Specifically, the contactors 210 are operable to electrically decouple or couple the battery pack 106 from/to a charge-discharge system of the EV 100. The charge-discharge system of the EV includes components that either charge the battery pack 106 or act as a load to draw electric power from the battery pack 106, and thus, may include the charge port 126, the power electronics module 108, and/or the transmission 110, among other components. While one contactor 210 is illustrated, multiple contactors 210 may be used. In addition, the contactors 210 may be placed in various suitable position in the EV 100, such as, but not limited to, between the positive power bus 206A and the power electronics module 108. In a non-limiting example, the contactor 210 may be provided as a relay or electromechanical switch.

In one form, the BMM 132 is configured to open or close the contactors 210 based on a message/request from the control system 130. In a non-limiting example, the control system 130 is configured to detect when the EV 100 is to be turned on or off based on an activation input (e.g., a user pressing a button associated with activating/deactivating the EV 100). If the EV 100 is to be turned on, the control system 130 provides an activation request to the BMM 132 to close the contactors 210, thereby electrically coupling the battery pack 106 to the charge-discharge system of the EV 100. If the EV 100 is to be turned off, the control system 130 provides a deactivation request to the BMM 132 to open the contactors 210, thereby electrically decoupling the battery pack 106 from the charge-discharge system of the EV 100. In addition, the control system 130 is configured to have the BMM 132 close the contactor 210 by sending the activation request when the battery pack 106 is to be charged, which may be detected by a sensor at the charge port (e.g., a sensor indicating the EVSE 122 is connected to the charge port 126, a sensor for detecting a charge port door (not shown) opening, and/or among other suitable charge detection methods).

Referring to FIG. 3, in one form, the BMM 132 includes an actuator 302 for operating the contactors 210 in the closed/open positions and a battery characteristic estimator (BCE) 304. The BCE 304 is configured to estimate various operational characteristics of the battery pack 106, such as, but not limited to, the OCV of each battery cell 204, the SOC of the battery pack 106, the power limit of the battery pack 106, and temperature(s) of the battery pack 106 or at other locations of the EV 100. As described in detail here, the BCE 304 includes a battery cell group (BCG) classifier 308, an OCV estimator 310 to estimate the OCV of the battery pack 106 (estimate OCV of each battery cell 204), and an OCV verification module 312.

In one form, BCG classifier 308 is configured to assign a battery cell 204 to a cell group among a plurality of cells group based on voltage measurements of the cells and a similarity algorithm. Once grouped, a group OCV is estimated for each cell group and a cell OCV for each battery cell is further estimated using the group OCV associated with the battery cell.

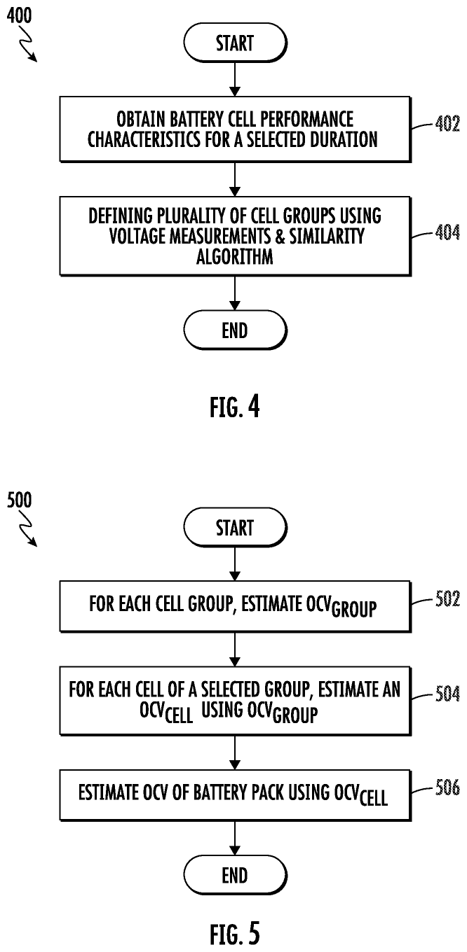

More particularly, referring to FIG. 4, an example battery cell group classifier routine 400 performed by the BCE 304 after deactivation, as part of the BCG classifier 308, is provided. At operation 402, the BCE 304 obtains performance characteristics of the battery cells 204 for a selected duration (e.g., 30 secs, 60 secs, 75 seconds, 90 secs). The performance characteristics includes voltage measurements of each battery cell. 204, and may also include temperature of the battery cells 204, array 202, or battery pack 106. In a non-limiting example, when the BCE 304 receives a deactivation request from the control system 130 to electrically disconnect the battery pack 106 from the charge-discharge system of the EV 100, the contactor 210 is opened, and the sensors 134 measure voltage of the battery cells 204 for a selected duration such as, but not limited to 25 sec., 30 sec, 60 secs, or 90 sec, and measure at least one temperature. In one form, the duration is less than an equilibrium time for active material of each of the battery cells 204 to equally distribute across an electrode of the battery cell 204. In one form, at least one temperature measurement is taken at the end of the selected duration after the contactor 210 is opened.

At operation 404, based on, at least, the voltage measurements, the BCE 304 is configured to define a plurality of cell groups using a similarity algorithm. Stated differently, the BCE 304 classifies or assigns battery cells 204 to a selected group based on how similar the voltage measurement of a selected battery cell 204 is to other cells 204. In one form, the similarity algorithm is based on Wasserstein metric (equation 1 below), which represents the distance between, for example, two curves (i.e., p=2) as the mean value of the sum of squared value of errors of different point, then take the root square value. In equation 1, “n” is the number of measurements (e.g., for a duration of 60 second, the BCE 304 has 61 measurements starting at time=0 and ending at time=60 sec); “P” is an empirical measure with samples X1, . . . . Xn; and “Q” is an empirical measure with samples Y=Y1, . . . , Yn. If two curves are similar, then the Wasserstein metric should be less than or equal to a voltage similarity threshold (V_{STH}), which is associated with the error/accuracy of the voltage sensor providing the voltage measurement and is a predefined value.

$${W}_{p} ( P , Q ) = {( \frac{1}{n} {\sum }_{i = 1}^{n} {‖ {X}_{( i )} - {Y}_{( i )} ‖}^{γ} )}^{1 / p} \qquad Equation 1$$

In a non-limiting example, voltage measurements for a first battery cell 204-1 (“V_{BC1}”) is associated with empirical measure P and voltage measurements for a second battery cell 202-2 (“V_{BC2}”) is associated with empirical measure Q. The distance between voltage measurements is provided as D(i)=V_{BC1}(i)−V_{BC2}(i). Based on the Waserstein metric, the similarity algorithm is provided as equation 2. With the value of W(P,Q), the BCE 304 groups battery cells 204 together if the value is less than or equal to the voltage similarity threshold (i.e., W(P,Q)≤V_{STH}).

$$W ( P , Q ) = {( \frac{1}{n} \times {\sum }_{i}^{n} ( {( D ( i ) - D ( 0 ) )}^{2} ) )}^{1 / 2} \qquad Equation 2$$

Once grouped, the OCV estimator 310 is configured to estimate the OCV of the battery pack 106 based on an estimated OCV of each battery cell that is determined using an estimated OCV of the group associated with the battery cell 204. More particularly, referring to FIG. 5, an example group OCV estimation routine is provided, and is executed by the BCE 304 as part of the OCV estimator 310.

At operation 502, the BCE 304 is configured to estimate the OCV for each group, which is referred to as a group OCV (i.e., OCV_{GROUP}), using at least a portion of the voltage measurement associated with the battery cells of the group. For example, the BCE 304 may determine an average voltage measurement set for the group, by calculating an average voltage measurement for each measurement time using the voltage measurements of the battery cells 204 associated with the group. In another example, the BCE 304 may use the voltage measurements associated with a selected battery cell 204 among the group to estimate the group OCV. The BCE 304 may select the battery cell 204 using various conditions such as, but not limited to, the selected battery cell has the lowest W(P,Q) or has a median voltage measurement.

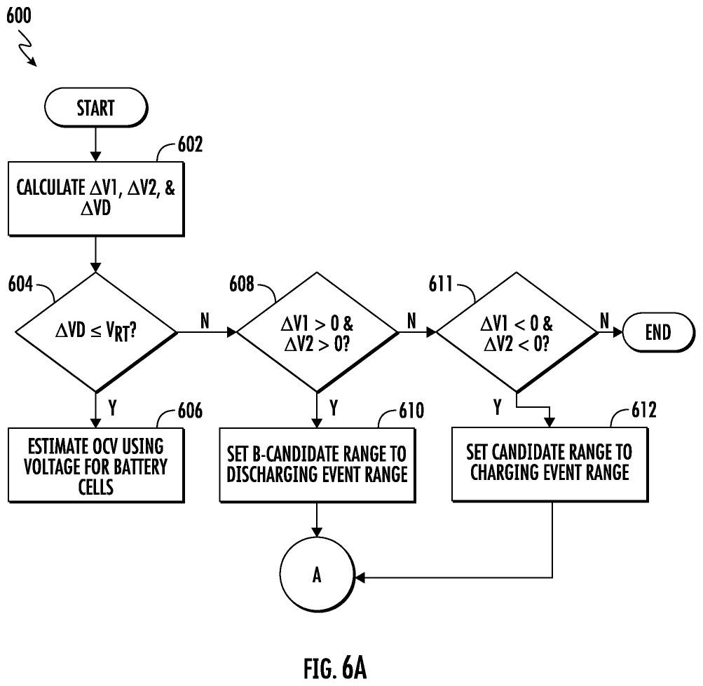

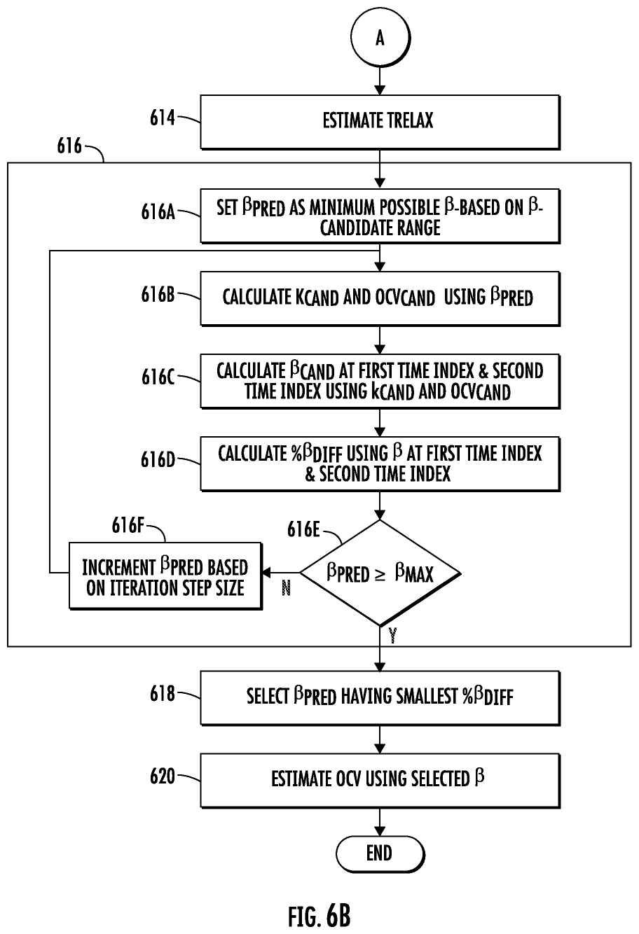

With defined group voltage measurements representative of the group (e.g., the average voltage measurement set or the voltage measurement of selected battery cell 204), the BCE 304 estimates the group OCV using various techniques. One technique is described further below with reference to FIGS. 6A and 6B.

At operation 504, using the group OCV, the BCE 304 is configured to estimate an OCV for each battery cell 204, which is referred to as a cell OCV (OCV_{CELL}). In one form, the cell OCV is determined based on an association between the group voltage measurements and the voltage measurements of the battery cell 204. In a non-limiting example, if the group voltage measurements are voltage measurements of a selected battery cell 204, the first voltage difference between the selected battery cell 204 and the respective battery cell 204 (i.e., voltage measurement at time=0) is added (or subtracted) to (or from) the group OCV to obtain the cell OCV for the respective battery cell 204. In another example, if the group voltage measurements are the average voltage measurements, a first voltage difference between the average voltage measurement at time=0 and the voltage measurement of the respective battery cell at time=0 is added (or subtracted) to (or from) the group OCV to obtain the cell OCV for the respective battery cell 204.

At operation 506, the BCE 304 estimates the OCV for the battery pack 106 by averaging the cell OCVs of the battery cells. The control system 130 employs the OCV to control the charging/discharging operation of the EV 100 by defining the power limits based on the OCV using known control techniques.

In one form, the OCV estimator 310 of the BCE 304 is configured to estimate the group OCV based on voltage measurements after a last deactivation of the EV 100 and a decay parameter that is a function of the voltages and a duration since the last deactivation. Specifically, the following technique for estimating an OCV can be employed for the OCV for each battery cell 204 using the voltage measurements for the battery cell 204 or for the group OCV using the group voltage measurements. Accordingly, to prevent narrow interpretation of the technique, the OCV provided below may be a group OCV or a cell OCV.

In one form, the BCE 304 employs equation 3 to estimate an OCV, where “V” is the voltage of the battery cell 204, and “DP” is the decay parameter.

$$V = O C V + D P \qquad Equation 3$$

In one form, the decay parameter has a non-linear correlation with voltage in that, after deactivation of the EV 100, the rate of change of voltage with time is not constant. The decay parameter of equation 3 characterizes the decaying voltage using an exponential parameter involving a square root of the duration, and further includes a coefficient and a constant that are a function of the voltages and battery temperature.

In one form, the decay parameter is provided as βe^{-\sqrt{kt}}, and includes sub-parameters such as β, k, and t. In the decay parameter, “β” is a coefficient related to SOC, temperature, and the magnitude of the current before contactors open; “k” is a time constant that is related to a diffusion coefficient in the electrodes, and likely follows an Arrhenius relationship (i.e., k=Ae^{-E}^{ₐ}^{/RT}); and “t” is time.

In one form, with the decay parameter being βe^{-\sqrt{kt}}, β at time “t” (i.e., βₜ) may be defined as equation 4 in which V(t) is a voltage measurement at time “t” and “V(0)” is voltage measured at t=0 seconds. Specifically, when t=0, equation 3 turns to V(0)=OCV+β, where OCV=V(0)−β. Substituting OCV in equation 3 with “V(0)−β,” β is then represented by equation 4. The sign of “β” is dependent on the direction of the current just before the battery pack 106 is decoupled. That is, if the battery pack 106 was being (predominately) discharged just before deactivation, the sign of β is negative indicating the voltage will be lower than the OCV. If the battery pack 106 was being (predominately) charged, β is positive.

$${β}_{t} = \frac{V ( t ) - V ( 0 )}{{e}^{- \sqrt{k * t}} - 1} \qquad Equation 4$$

In some example systems, the decay parameter, and specifically β and k, are estimated using complex regression models using voltage measurements taken for a selected duration, such as one minute. However, such estimation techniques may require computational power that can exceed hardware limitations of the BMM 132.

As detailed herein, k is defined in terms of β, and β is estimated using a detected or selected relaxation time (t_{RELAX}) from among a plurality of calibrated relaxation times and by comparing predicted β (i.e., βpred) across a range of candidate β (βcand). Specifically, at a relaxation time, which is some time after a relaxation process starts and voltage measurement accuracy is less than or equal to the voltage sensor error (V_{SE}), which may be based, at least, on accuracy/error of the voltage sensors providing the voltage measurements, then at the relation time (i.e., t=t_{RELAX}), |V(t_{RELAX})−OCV|≤V_{SE}. In one form, the relaxation time is estimated based on a temperature of the battery pack 106, an absolute delta voltage (i.e., absolute change in voltage) estimated using at least a portion of the voltages measured, and relaxation time correlation data that associates selected inputs (e.g., the temperature and the absolute delta voltage) to associated relaxation times. In a non-limiting example, the relaxation correlation data is provided as a one or more look-up tables. In one form, the voltage relaxation threshold may be the same as the voltage similarity threshold.

By setting time as the relaxation time in equation 4, k is expressed as a function of β, voltage sensor error (V_{SE}), and the relaxation time (t_{RELAX}), as provided in equation 5.

$$k = \frac{{ln [ \frac{{V}_{S E}}{{β}_{cand}} ]}^{2}}{{t}_{RELAX}} \qquad Equation 5$$

Referring to FIGS. 6A and 6B, an example an OCV estimation routine 600 is provided and executable by the BCE 304, and may be part of the OCV estimator 310. As detailed herein, the BCE 304 estimates the OCV based on voltages measured for a duration after a last deactivation of the EV and a decay parameter that is a function of the voltages measured and detected using a selected relaxation time and an iterative estimation of a sub-parameter of the decay parameter. The control system 130 is configured to charge and discharge the battery pack 106 according to power limits defined at activation of the EV 100 by the estimated OCV.

At operation 602, using the performance characteristics (e.g., the group voltage measurements), the BCE 304 determines if the battery pack 106 was significantly charging or discharging prior to deactivation. Specifically, at operation 602, the BCE 304 calculates a plurality of delta voltages to assess if the voltage is substantially decreasing or increasing. In a non-limiting example, the BCE 304 calculates delta voltage values ΔV1, ΔV2, and ΔVD using ΔV1=V(t_{D})−V(t₁), ΔV2=V(t₁)−V(0), and ΔVD=|V(t_{D})−V(0)|, where: V(t_{D}) is voltage measured at end of the duration; V(t₁) is voltage measured at time=t₁, where t₁ is a time between zero (0) and the duration (e.g., if duration is 30 second, t₁ is time=15 sec); and V(0) voltage measured at time zero (0) when the EV 100 is deactivated.

At operation 604, the BCE 304 is configured to determine if the voltage is at relaxation or stated differently, if the voltage measured is the OCV. More specifically, at operation 604, the BCE 304 determines if ΔVD| is less than or equal to the voltage relaxation threshold (V_{RT}) (i.e., |V(t_{D})−V(0)|≤V_{RT}). If so, at operation 606, the BCE 304 estimates the OCV by, for example, averaging the voltage measured at t₁ for the battery cells 204. This may occur in various scenarios, such as, but not limited to, the EV 100 being turned off for 6 hrs, then being turned on for a few minutes, and then being turned off without significant charge or discharge. In such a case, the battery pack 106 reached relaxation time and the voltage measured is indicative of OCV. The voltage delta threshold is selected to detect a significant voltage rise or fall using the voltage measured for the duration. In a non-limiting example, the voltage delta threshold is provided as 4*V_{SE}.

If the voltage is not at relaxation (i.e., ΔVD>V_{RT}), the BCE 304 determines if the EV 100 was charging or discharging prior to deactivation. Specifically, at operation 608, the BCE 304 determines if the delta voltage values are greater than zero (i.e., ΔV1>0 and ΔV2>0). If the delta voltage values are both greater than zero, the EV 100 was discharging prior to deactivation. If both of the delta voltage values are less than zero (i.e., (i.e., ΔV1<0 and ΔV2<0), as determined at operation 611, the EV 100 was charging prior to deactivation. Otherwise, the BMM 132 is unable to determine either charging or discharging, and the process ends without determining OCV.

From operations 608 and 611, the BCE 304 sets a candidate range at a defined iteration step size for β based on whether the EV 100 was discharging or charging. Specifically, for the iterative estimation, the BCE 304 employs a discharging event range of values for β, a sub-parameter, in response to detecting that the battery pack 106 was discharging prior to the last deactivation. That is, when the EV 100 was discharging, β is a negative value, and at operation 610, the BCE 304 sets the β-candidate range to the discharging event range where the β-candidate range is provided as: V(0)−OCV(100)≤βcand≤0 in which OCV(100) is the OCV when the SOC is at 100%, which may be defined and stored by the BCE 304, and V(0) is the voltage measured at time zero.

The BCE 304 employs a charging event range of values for β in response to detecting that the battery pack 106 was charging prior to the last deactivation. That is, when the EV was charging, β is a positive value, and at operation 612, the BCE 304 sets the β-candidate range to the charging event range where the β-candidate range is provided as: 0≤βcand≤V(0)−OCV(0) in which OCV(0) is the OCV when the SOC is at 0%. The discharging event range for β may be referred to as a first sub-parameter candidate range of values, and the charging event range for β may be referred to as a second sub-parameter candidate range of values.

At operation 614 and as described above, the BCE 304 is configured to detect or select the relaxation time (t_{RELAX}) using the relaxation time correlation data with inputs including temperature (T) and an absolute delta voltage that is estimated using at least a portion of the voltages measured (e.g., ΔVD|). In one form, the temperature and voltage measurements used are taken at about the same time, which may be determined using a time stamp associated with the measurements.

At operation 616, the BCE 304 is configured to perform the iterative estimation to estimate β (i.e., sub-parameter) within the candidate range at a defined iteration step size. Specifically, at operation 616A, the BCE 304 is configured to set a value for a predicted β (β_{PRED}) to the minimum possible value of β, which is defined by the β candidate range defined at operation 612 or 614. For example, for the discharging event range, β_{PRED}=V(0)−OCV(100), and for the charging event range, β_{PRED}=0V.

At operation 616B, using the β_{PRED} and t_{RELAX}, the BCE 304 is configured to estimate a k-candidate (k_{CAND}) and an OCV-candidate (OCV_{CAND}). In a non-limiting example, the k-candidate is calculated using equation 5 and the OCV-candidate is calculated by OCV=V(0)−β_{PRED}.

At operation 616C, the BCE 304 is configured to estimate β-candidate at a first time index (β_{CAND-TI1}) and at a second time index (β_{CAND-TI2}) using k-candidate, the OCV-candidate, and voltage measurements associated with the first time index and the second time index. Specifically, the BCE 304 calculates B at least at two selected points in time (i.e., time indexes). In a non-limiting example, the BCE 304 employs equation 6 below to determine β-candidate at a selected time index (i.e., β_{CAND-TI}) in which V(t) is the voltage measured at the time index and t is the time index. The time indexes may be predefined and selected based on the duration. For example, if the duration is 60 secs, the first time index is 30 secs and the second time index is 60 secs. Accordingly, β_{CAND-TI1} is calculated using data related to t=30 seconds and β_{CAND-TI2} is calculated using data related to t=60 seconds.

$${β}_{CAND - TI} = \frac{V ( t ) - O C {V}_{CAND}}{{e}^{- \sqrt{{k}_{{CAND}^{* t}}}}} \qquad Equation 6$$

At operation 616D, the BCE 304 is configured to estimate an error or, stated differently, a difference between β_{CAND-TI1} and β_{CAND-TI2}. Generally, B should be constant and thus, the smaller the difference between β_{CAND-TI1} and β_{CAND-TI2}, the more accurate β_{CAND} is to a true β at OCV. In a non-limiting example, the BCE 304 calculates a percent error or difference (i.e., % β_{DIFF}) using equation 7.

$$\% {β}_{DIFF} = \vert ( \frac{( {β}_{CAND - {TI}_{1}} - {β}_{CAND - {TI}_{2}} )}{{β}_{CAND - {TI}_{1}}} ) \vert \qquad Equation 7$$

At operation 616E, the BCE 304 is configured to determine if the predicted β is greater than or equal to a maximum possible value of β (i.e., β_{MAX}), which is defined by the β candidate range defined at operation 610 or 612. For example, for the discharging event range, maximum possible value of β is zero and for the charging event range, the maximum possible value of β is V(0)−OCV(0), where OCV(0)=OCV at SOC=0%.

If the predicted β is not greater than or equal to the maximum possible value of β, the BCE 304 is configured to increment β_{PRED} based on the iteration step size, at operation 616F. That is, the BCE 304 iteratively increments the value of the predicted β based on a selected step size to estimate β-candidates at the time indexes across the β-candidate range. In a non-limiting example, the steps size is set to 0.001 or 0.01V. A small iteration step size provides a more refined evaluation of β, but also increases the computational load than compared to a larger iteration step size.

If the predicted β is greater than to the maximum possible value of β, the BCE 304 is configured to select the value of β as the value of the β_{CAND} having smallest % β_{DIFF}, at operation 618. For example, the BCE 304 uses the value of the β_{CAND-TI1} having the lowest % β_{DIFF} as β. In one form, of all β search values, there is one value that gives the closest estimation of OCV and is between β_{CAND-TI1} and β_{CAND-TI2}. Accordingly, the BCE 304 may be configured to determine the β value between β_{CAND-TI1} and β_{CAND-TI2} using various techniques, such as but not limited to interpolation. Using, the selected B, which may be referred to as predicted first sub-parameter, the BCE 304 estimates the OCV using OCV=V(0)−β, at operation 620. With the OCV, the BCE 304 is configured to estimate an initial state of charge of the battery pack based on the estimated OCV, where the power limits are defined, in part, by the initial state of charge.

In another variation, in lieu of calculating % β_{DIFF} at 616D, the BCE 304 is configured to calculate % β_{DIFF} after all search steps are complete (i.e., after 616E).

If determining the group OCV, the BCE 304 is configured to return to operation 504 of FIG. 5 to determine the cell OCVs and the OCV of the battery pack 106. By assigning the cells 204 into groups and determining the cell OCV using the group OCV, the computational load of the BMM 132 may be reduced.

In one form, after estimating the OCV of the battery pack 106, using any particular techniques including, but not limited to those described herein, the present disclosure provides a method for detecting whether the estimated OCV is accurate. Specifically, the OCV verification module 312 of the BCE 304 is configured to confirm whether the estimated OCV after the last deactivation, which is referred to as an OCV_{KEY-OFF}, is accurate based on an estimated OCV detected after the activation of the EV 100, which is referred to as an OCV_{KEY-ON}. If the estimated OCV is within an OCV estimation threshold, then the OCV_{KEY-OFF} is verified and employed for controlling the EV 100. On the other hand, if the OCV_{KEY-OFF} is not within the OCV estimation threshold, then the OCV_{KEY-OFF} is not used to control the EV 100.

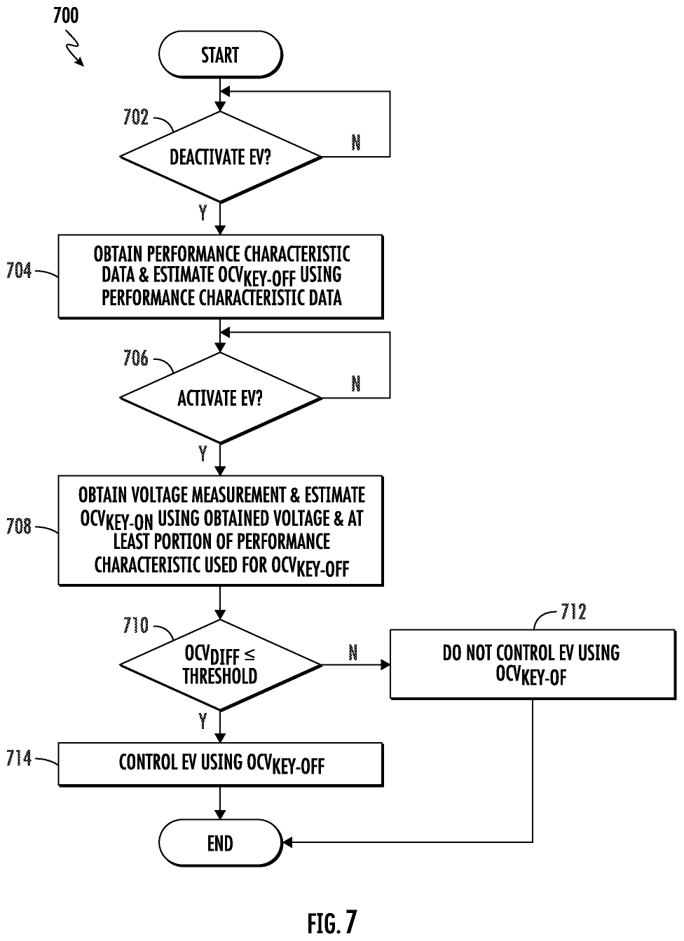

More particularly, referring to FIG. 7, an example verification routine 700 performed by the BCE 304, as part of the OCV verification module 312 is provided. At operation 702, BCE 304 determines if the EV 100 is to be deactivated. For example, the BCE 304 determines if a deactivation request from the control system 130 to electrically disconnect the battery pack 106 from the charge-discharge system of the EV 100 is received. If so, the BCE 304 opens the contactor 210. At operation 704, the BCE 304 obtains the performance characteristic data (e.g., voltage measurements and temperature measurement(s)) similar to operation 402 of FIG. 4, and estimates the OCV_{KEY-OFF}.

In one form, the OCV_{KEY-OFF} is estimated using the grouping techniques of FIGS. 4 and 5. In another form, the OCV_{KEY-OFF} is estimated by estimating the OCV for each battery cell using the technique of FIGS. 6A and 6B, and then aggregating the cell OCVs to determine the OCV_{KEY-OFF} for the battery pack 106.

At operation 706, the BCE 304 determines if the EV 100 is to be activated. For example, the BCE 304 determines if an activation request from the control system 130 to electrically connect the battery pack 106 to the charge-discharge system of the EV 100 is received. If so, prior to the BCE 304 closing the contactor 210, at operation 708, the BCE 304 obtains voltage measurement for the cells after activation request received but prior to the contactor 210 being closed (i.e., V(t_{KEY-ON})). Once measurement is obtained, the contactor 210 may be closed. At operation 708, the BCE 304 also estimates an OCV_{KEY-ON}, which is an OCV estimated based on at least some of the performance characteristics taken after deactivation and the voltage measurements taken after receiving the activation request. In a non-limiting example, the BCE 304 employs the voltage measurements taken at time=0 and t_{D} (i.e., at end of measurement duration) after deactivation, and V(t_{KEY-ON}). OCV_{KEY-ON} is estimated in a similar manner as that of OCV_{KEY-OFF}.

At operation 710, the BCE 304 is configured to determine whether a difference between OCV_{KEY-OFF} and OCV_{KEY-ON} is less than or equal to the OCV estimation threshold (i.e., OCV_{DIFF}≤OCV estimation threshold, where OCV_{DIFF}=|OCV_{KEY-OFF}−OCV_{KEY-ON}|). In one form, the OCV estimation threshold is associated with the accuracy/error of the voltage sensor(s) employed for measuring the voltage of the battery cells 204, and may be the same as the voltage similarity threshold and/or voltage relaxation threshold. In another form, the OCV estimation threshold is determined based on other battery control application need, such as state of health (SOH) estimations. In a non-limiting form, the OCV estimation threshold may be 2*V_{SE}.

If the difference between OCV_{KEY-OFF} and OCV_{KEY-ON} is less than or equal to the OCV estimation threshold, the OCV KEY-OFF is used to control the EV 100, at operation 714. If the difference between OCV_{KEY-OFF} and OCV_{KEY-ON} is greater than the OCV estimation threshold, OCV_{KEY-OFF} is not used to control the EV 100. Instead, the EV 100 may use the OCV_{KEY-ON} or previously used OCV, at operation 712. Accordingly, the OCV verification technique of the present disclosure does not use an OCV that is believed to be outside a desired accuracy level.

The routines 400, 500, 600, and 700 are just one example of implementing selected features of the BCE 304. It should be readily understood that the routines may be configured in other suitable ways within the scope of the present disclosure. In a non-limiting example, in routines 500, 600, and 700, different OCVs described herein may be estimated after activation of the EV 100 where the performance characteristics measured for determining the OCVs may be stored by the BCE 304.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

In this application, the term “module” and/or “controller” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory or memory device is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A system for an electrified vehicle (EV) having a battery pack, comprising:
a vehicle controller configured to charge and discharge the battery pack according to power limits defined at activation of the EV by a first open circuit voltage (OCV) estimated after a last deactivation of the EV based on voltages measured for a first duration after the last deactivation in response to the first OCV being within an OCV estimation threshold of a second OCV estimated after activation of the EV based on at least a portion of the voltage measured for the first duration and voltages measured prior to a contactor closing to activate the EV.

2. The system of claim 1, wherein the OCV estimation threshold is associated with an accuracy threshold of a voltage sensor measuring the voltages measured.

3. The system of claim 1, wherein:
the voltages measured after the last deactivation and prior to a contactor closing to activate the EV includes voltage measurements for each battery cell of the battery pack, and
the vehicle controller is configured to estimate a cell OCV for each battery cell using the voltages measured and the first OCV is an average of the cell OCVs based on the voltages measured after the last deactivation, and the second OCV is an average of the cell OCVs based on at least the portion of the voltage measured for the first duration and the voltages measured prior to the contactor closing.

4. The system of claim 1, wherein:
the voltages measured after the last deactivation and after activation request includes voltage measurements for each battery cell among a plurality of battery cells of the battery pack, and
the vehicle controller is configured to estimate the first OCV and the second OCV based on a cell OCV for each battery cell that is estimated using a group OCV associated with the battery cell and, for the first OCV, the voltages measured after the last deactivation and for the second OCV, at least the portion of the voltage measured for the first duration and the voltages measured prior to the contactor closing.

5. The system of claim 4, wherein the vehicle controller, for each of the first OCV and the second OCV, is configured to:
assign each battery cell to a group defining a plurality of cell groups using a similarity algorithm and the voltage measurements of the battery cells, and
estimate the group OCV for each cell group based on at least a portion of the voltage measurements.

6. The system of claim 5, wherein the similarity algorithm is based on Wasserstein metric.

7. The system of claim 1, wherein the first duration us less than a stabilization time for active material of each battery cell of the battery pack to equally distribute across an electrode of the battery cell.

8. The system of claim 1, wherein the first OCV and the second OCV are further estimated using a decay parameter that is a function of the voltages measured and detected using a selected relaxation time and an iterative estimation of a sub-parameter of the decay parameter.

9. A system for an electrified vehicle (EV) having a battery pack, comprising:
a vehicle controller configured to charge and discharge the battery pack, having a plurality of battery cells, according to power limits defined at activation of the EV by an estimated open circuit voltage (OCV) based on a cell OCV for each of the battery cells that is estimated using a group OCV associated with each of the battery cells assigned to a cell group.

10. The system of claim 9, wherein each of the battery cells is assigned to the cell group via a similarity algorithm that is based on Wasserstein metric.

11. The system of claim 9, wherein the vehicle controller is configured to estimate the group OCV using voltage measurements associated with a selected battery cell from among the battery cells of the cell group.

12. The system of claim 11, wherein the vehicle controller is configured to estimate the cell OCV for each battery cell of the cell group based on a voltage difference between a voltage measurement of a respective battery cell and the selected battery of the cell group.

13. The system of claim 9, wherein, for each group OCV, the group OCV is estimated using an average voltage of voltage measurements associated with the battery cells of the cell group.

14. The system of claim 13, wherein the vehicle controller is configured to estimate the cell OCV for each battery cell of the cell group based on a voltage difference between a voltage measurement of a respective battery cell and the average voltage of the cell group.

15. The system of claim 9, wherein the vehicle controller is configured to estimate the group OCV using group voltage measurements defined based on a voltage measurement of each battery cell and a decay parameter that is a function of the group voltage measurements and detected using a selected relaxation time and an iterative estimation of a sub-parameter of the decay parameter.

16. The system of claim 9, wherein the vehicle controller is further configured to use the estimated OCV, as a first OCV, in response to the first OCV being within an OCV estimation threshold of a second OCV estimated after an activation request based on at least one voltage measured after the activation request and prior to a contactor closing.

17. A method of controlling an electrified vehicle (EV) having a battery pack including a plurality of battery cells, comprising:
responsive to a deactivation request, opening one or more contactors to electrically decouple the battery pack from a charge-discharge system of the EV;
responsive to an activation,
closing the one or more contactors to electrically couple the battery pack to the charge-discharge system, and
charging and discharging the battery pack according to power limits defined at activation of the EV by a first open circuit voltage (OCV) estimated after a last deactivation of the EV based on voltages measured for a first duration after the last deactivation in response to the first OCV being within an OCV estimation threshold of a second OCV estimated after activation of the EV based on at least a portion of the voltage measured for the first duration and voltages measured prior to a contactor closing to activate the EV.

18. The method of claim 17, wherein:
the voltages measured after the last deactivation and after activation includes voltage measurements for each battery cell of the battery pack, and
the method further includes estimating a cell OCV for each battery cell using the voltages measured, the first OCV being an average of the cell OCVs based on the voltages measured after the last deactivation, and the second OCV being an average of the cell OCVs based at least the portion of the voltage measured for the first duration and the voltages measured prior to the contactor closing.

19. The method of claim 17, wherein:
the voltages measured after the last deactivation and after activation include voltage measurements for each battery cell among a plurality of battery cells of the battery pack, and
the method further comprises estimating the first OCV and the second OCV based on a cell OCV for each battery cell that is estimated using a group OCV associated with the battery cell and, for the first OCV, the voltages measured after the last deactivation and for the second OCV, at least the portion of the voltage measured for the first duration and the voltages measured prior to the contactor closing.

20. The method of claim 19, further comprising for each of the first OCV and the second OCV:
assigning each battery cell to a group defining a plurality of cell groups using a similarity algorithm and the voltage measurements of the battery cells, the similarity algorithm being based on Wasserstein metric; and
estimating the group OCV for each cell group based on at least a portion of the voltage measurements.
